(19) United States
(12) Patent Application Publication
(10) Pub. No.: US 2020/0059071 A1
(43) Pub. Date: Feb. 20, 2020

(54) HIGH-EFFICIENCY OXIDE VCSEL MANUFACTURING METHOD THEREOF

(71) Applicant: AUK CORP., Iksan-si (KR)

(72) Inventor: Hyung Joo LEE, Iksan-si (KR)

(73) Assignee: AUK CORP., Iksan-si (KR)

(21) Appl. No.: 16/370,860

(22) Filed: Mar. 29, 2019

(30) Foreign Application Priority Data
Aug. 20, 2018 (KR) 10-2018-0096730

(51) Int. Cl. H01S 5/183; H01S 5/187; H01S 5/00; H01S 5/323; H01S 5/022

(52) U.S. Cl. CPC H01S 5/18313; H01S 5/187; H01S 5/02296; H01S 5/0064; H01S 5/32308; H01S 5/18394

(57) ABSTRACT

The present invention relates to a vertical cavity surface emitting laser (VCSEL) and a manufacturing method thereof, and more specifically, to a high-efficiency oxidation VCSEL which emits laser beams having a peak wavelength of 860 nm, and a manufacturing method thereof.

### BACKGROUND OF THE INVENTION

### Priority Claim

This application claims the benefit of prior Korean Application No. KR 10-2018-0096730 filed on Aug. 20, 2018, which is incorporated by reference in its entirety.

### Field of the Invention

The present invention relates to a vertical cavity surface emitting laser (VCSEL) and a manufacturing method thereof, and more specifically, to a high-efficiency oxidation VCSEL which emits laser having a peak wavelength of 860 nm, and a manufacturing method thereof.

### Background of the Related Art

Although the efficiency of a general vertical cavity surface emitting laser (VCSEL) is lower than that of an existing surface emitting laser, since laser is emitted in the vertical direction to substrate. Therefore, VCSELs can be used in the region of an existing light emitting diode and thus has high marketability.

As shown in FIG. 1, the VCSEL 10 like this has a structure of stacking a bottom electrode 1, a substrate 2, a bottom distributed Bragg reflector 3, an active layer 4, a current window 5 for emitting cavity laser beams, an oxidized layer 6 formed to surround the current window, a top distributed Bragg reflector 7 formed on the top surface of both the current window 5 and the oxidized layer 6, and a top electrode 8. A trench 9 is formed, and the laser beams are emitted upward.

Generally, the trench 9 is a circular shape formed by using a dry etching technique. The oxidized layer 6 is formed by oxidizing the periphery of the current window 5 using an oxidant injected through the trench 9 and adjusts the diameter of the unoxidized remaining current window 5 by controlling the oxidation time. In addition, top and bottom DBRs are applied to the top and bottom of the active layer through an epitaxial process. In the case of a VCSEL which emits light of 800 to 1,000 nm, a DBR of a stack structure configured of AlₓGa₁₋ₓAs/Al_{y}Ga_{1-y}As, where 0.8<x<1 and 0<y<0.2, is generally used.

Accordingly, the current window (oxide aperture) and the top and bottom DBRs are essential for the characteristic of the cavity laser in the manufacturing process, and the problem is that since the materials used in these two components are materials of the same kind, the probability of generating a defect is high as the uppermost part of the top p-DBR is oxidized together with the current window in the oxidation process for forming the current window. The oxidation is a process of manufacturing an AlxOy layer by injecting H₂O steam and reacting Al of an Al_{0.98}Ga_{0.02}As layer used as the current window using high temperature steam. Therefore, they are oxidized together to some extent since the top and bottom DBRs made of AlxGa1-xAs/AlyGa1-yAs contained Al.

FIG. 2(a) shows an SEM image of a DBR damaged during oxidation is progressed, and when a p-metal is applied to a damaged DBR sample, electrode peeling or uneven current injection (reduction of efficiency) may be generated later. FIG. 2(b) shows a shape of the current window, and the black stripe is a trench (pitted) area, and the area in the middle is a pillar area for emitting light, in which the brighter area is an oxidized area. The dark circular area at the center is the light emitting area directly emitting light and is marked as an aperture diameter in the VCSEL.

Since the elements of a conventional VCSEL generate much heat when high current is applied by the nature of resonance and, therefore the elements are damaged frequently as high current is applied. Based on this reason, current spreading effect cannot be expected much from the current injected from the electrode. Therefore, since the current emitted from the top electrode positioned along the edge of the top DBR does not evenly pass through the current window at the center, there is a problem of lowering the efficiency.

Korean Laid-opened Patent No. 10-2018-0015630 (WO 2016/198282) discloses an oxide VCSEL having a peak wavelength of 350 nm and a method of diversely forming a plurality of oxidized layers inside the top DBR to improve the oxide VCSEL. This manufacturing process primarily generates uneven top DBR reflectivity and also causes a complicated problem in oxidation reprocess or the like for creating several current windows.

Meanwhile, as a measure for evenly passing the current emitted from the top electrode through the current window at the center, a transparent ITO layer is formed all over the top DBR to evenly supply the current emitted from the electrode of a ring shape to the center through the ITO. However, in this case, an expensive transparent electrode is required, and it is difficult to avoid abrupt reduction of throughput in the process of forming the ITO.

### SUMMARY OF THE INVENTION

Therefore, the present invention has been made in view of the above problems, and it is an object of the present invention to provide a method of preventing damage of a top DBR in the process of manufacturing an oxide VCSEL.

Another object of the present invention is to provide a method of manufacturing an oxide VCSEL by inducing stable flow and spread of electricity from a top electrode of a VCSEL to a light emitting area in active region.

Another object of the present invention is to provide a high conductivity barrier layer, which can prevent damage of a top DBR in an oxidization process of an oxide VCSEL, induce stable flow and spread of electricity from a top electrode to a light emitting area, and is transparent to the light emitted from the oxide VCSEL.

Another object of the present invention is to provide a thickness of a high conductivity barrier layer, appropriate to prevent damage of a top DBR in an oxidization process of an oxide VCSEL, to induce stable flow and spread of electricity from a top electrode to a light emitting area, and to be transparent to the light emitted from the oxide VCSEL, by covering the top DBR so that efficiency of the VCSEL can be enhanced remarkably.

To accomplish the above objects, according to one aspect of the present invention, there is provided an oxide vertical cavity surface emitting laser (VCSEL) having a conductive current spreading layer formed between a top electrode and a top distributed Bragg reflector to pass a laser having a peak wavelength of 860±10 nm (hereinafter, referred to as a ‘860 nm peak wavelength’).

In the present invention, it is understood that a laser has a wavelength having a full-width at half-maximum (FHWM) of 5 nm or smaller.

In the present invention, the current spreading layer is preferably a non-oxidizing barrier layer to prevent damage of a top DBR by covering the top DBR in an oxidization process of the VCSEL.

In an embodiment of the present invention, the current spreading layer may be an Al-free layer that does not include an Al component to prevent oxidization by water steam, further preferably, a conductive GaP layer, having relatively high transparency with respect to a laser having a peak wavelength of 860 nm to enhance efficiency of the oxide VCSEL in the stacking process.

In the present invention, the GaP layer may include a metallic or non-metallic dopant to improve conductivity. An example of the metallic dopant, is magnesium (Mg) or zinc (Zn), and the non-metallic dopant may be carbon.

In the present invention, the current spreading layer preferably has a thickness of 1 μm or larger so that the current supplied to the active layer may sufficiently spread. If the thickness is small, spread of the current is insufficient, and improvement in the efficiency of the oxide VCSEL according to adoption of the current spreading layer is small. In the present invention, it is preferable to increase the thickness of the current spreading layer as much as a thickness that does not have an effect of improving efficiency according to increase of thickness because of saturation (saturation thickness). In an embodiment of the present invention, when the VCSEL has a current window of a 10 μm diameter, the saturation thickness may be 3 μm.

In the present invention, an oxide vertical cavity surface emitting laser (VCSEL) may include a bottom electrode, a substrate, a bottom distributed Bragg reflector, an active layer, a top distributed Bragg reflector, a top electrode and an oxidized layer.

In the present invention, the active layer of the VCSEL is an active layer which can emit light having a peak wavelength of 850±10 nm (hereinafter, referred to as a 850 nm peak wavelength). In an embodiment of the present invention, the active layer may include a GaAs quantum well and an AlGaAs quantum barrier layer.

In the present invention, the top distributed Bragg reflector and the bottom distributed Bragg reflector are used to reflect up and down the light emitted from the active layer so that the light may resonate.

In the present invention, the top and bottom DBRs may be DBRs repeatedly stacked reflective layers, which is configured of a pair of a high refractive layer and a low refractive layer, to reflect the light emitted from the active layer.

In an embodiment of the present invention, thirty or more pairs, preferably forty pairs of n-DBRs, may be used in the bottom DBR to almost perfectly reflect the light reflected by the active layer and the top DBR. The top DBR may be p-DBRs, having five to ten pairs less than the bottom DBR, and having preferably twenty to twenty-five pairs of p-DBRs, to enhance the possibility of emitting light.

In an embodiment of the present invention, the top distributed Bragg reflector and the bottom distributed Bragg reflector may be distributed Bragg reflectors (DBRs) having a structure repeatedly stacking an AlₓGa₁₋ₓAs layer of 0.8<x<1 and an Al_{y}Ga_{1-y}As layer of 0<y<0.2.

In the present invention, the oxidized layer is configured of an oxidizing material and may mean a layer in which an oxidized area and a non-oxidized area commonly exist for resonance. The oxidized layer may be Al_{z}Ga_{1-z}As of 0.95<z≤1 to be easily oxidized by high temperature steam. The oxidized layer is oxidized from the outer part toward the center, and thus, may be configured of an oxidized layer of a ring shape and a non-oxidized layer of center circle, which may become a current window.

In the present invention, the diameter of the center circle configuring the current window in the oxidized layer should be as narrow as to be able to emit laser beams and may be 10 μm or smaller preferably.

In the present invention, the oxidized layer may be positioned on the top of the active layer and preferably positioned inside the top p-DBR, preferably between layers configuring the p-DBR, not to affect the active layer. Further preferably, the oxidized layer may be positioned on the lower part of the top p-DBR, e.g., between a first pair and a second pair in the top p-DBR, and may be applied at a thickness of 30 to 100 nm.

In an embodiment of the present invention, the oxide VCSEL may operate at a current of 10 to 40 mA, preferably in a range of 25 to 35 mA, and most preferably in a range of 30 to 35 mA. When the current is 10 mA or lower, laser beams are not generated, and when the current is 40 mA or higher, a laser beam having a peak wavelength of 860 nm may not be generated due to the effect of heat generation.

In the present invention, the top electrode may be configured in a ring shape not to block emitted light, and preferably, it may be a multilayer electrode configured of Au/Pt/Ti. In an embodiment, the thickness of electrode may be about 2 micrometers.

In the present invention, the oxide VCSEL may further include an anti-reflection layer to prevent reflection of emitted light. The anti-reflection layer may be positioned between the current spreading layer and the top electrode while covering the current spreading layer. In addition, the anti-reflection layer may be positioned at the uppermost part of the oxide VCSEL while covering the top electrode and the top of the anti-reflection layer.

In an embodiment of the present invention, the anti-reflection layer may be configured of SiNx or SixOy and applied to grow at a thickness of 100 to 500 nm. The anti-reflection layer is preferably 150 to 400 nm, further preferably 200 to 300 nm.

In an aspect of the present invention, there is provided a method of manufacturing an oxide VCSEL having a peak wavelength of 860 nm, in which a GaP layer having a thickness of 1 μm or larger is formed between a top electrode and a top DBR.

### BRIEF DESCRIPTION OF THE DRAWINGS

FIG. 1 is a view showing an exploded cross-section of a conventional oxide VCSEL.

FIG. 2(a) is a view showing an SEM image of a DBR damaged when oxidation is progressed, and FIG. 2(b) is a view showing a shape of a current window, in which the black stripe is a trench (pitted) area, and the area in the middle is a pillar area for emitting light, and the brighter area is an oxidized area.

FIG. 3(a) is a separate cross-sectional view showing a layer structure of an oxide VCSEL according to an embodiment of the present invention, and FIG. 3(b) is a view showing distribution of light emitted from an active layer and light of a resonated laser, (inverse peak is cavity peak).

FIG. 4 is a view showing the wavelength of an active layer and the cavity peak of an oxide VCSEL according to the present invention.

FIG. 5 is a graph showing emission intensity when a 20 mA current is applied to (a) a VCSEL without a GaP in comparative example 1, (b) a VCSEL having a GaP of 1 μm thick in embodiment 1, (c) a VCSEL having a GaP of 3 μm thick in embodiment 2, and (d) a VCSEL having a GaP of 6 μm thick in embodiment 3.

FIG. 6 shows SEM images of the side surfaces of a VCSEL without a GaP layer and 860 nm VCSELs to which GaP barriers of diverse thicknesses are applied and shows mimetic views of current injection paths and light emission.

FIG. 7 is a view showing (a) an I-V curve and (b) an I-L curve of VCSELs respectively having a thickness of 1, 3 and 6 μm in comparative (conventional) example 1 and embodiments 1 to 3 according to application of current of 0 to 50 mA in the present invention.

FIG. 8 is a graph showing the current-voltage characteristics of a GaP layer and an AlGaAs layer.

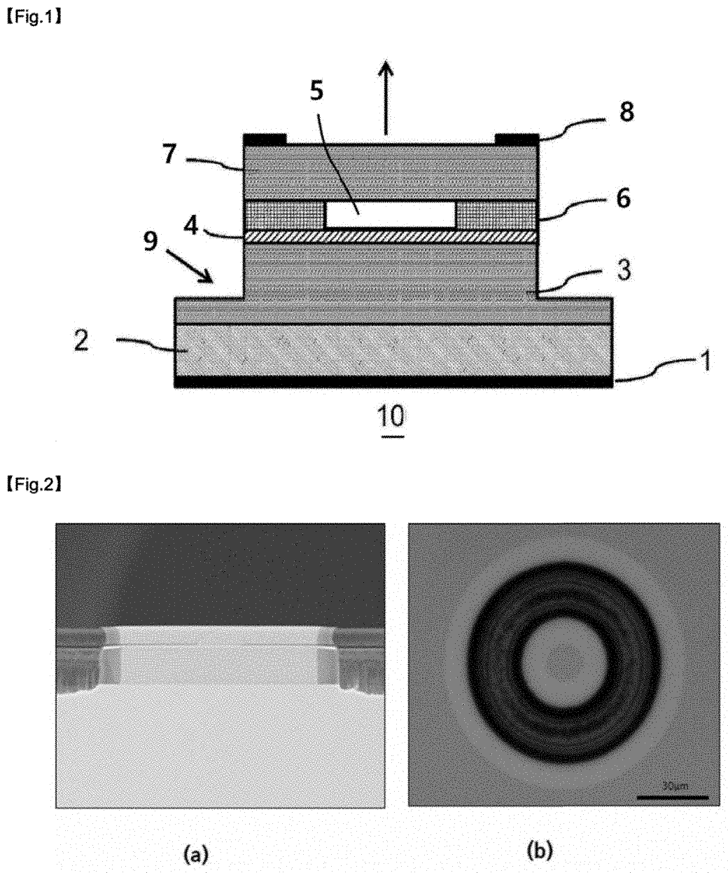

DESCRIPTION OF SYMBOLS

| | |
|---|---|
| 100: Oxide VCSEL | 110: Bottom electrode |
| 120: Substrate | 130: Bottom DBR |
| 140: Active layer | 150: Top DBR |
| 160: GaP layer | 170: Top electrode |
| 180: Oxidized layer | |

### DETAILED DESCRIPTION OF THE PREFERRED EMBODIMENT

Hereafter, the present invention will be described in detail through embodiments. The embodiments described below are intended not to limit, but to illustrate the present invention.

### Embodiments 1 to 3

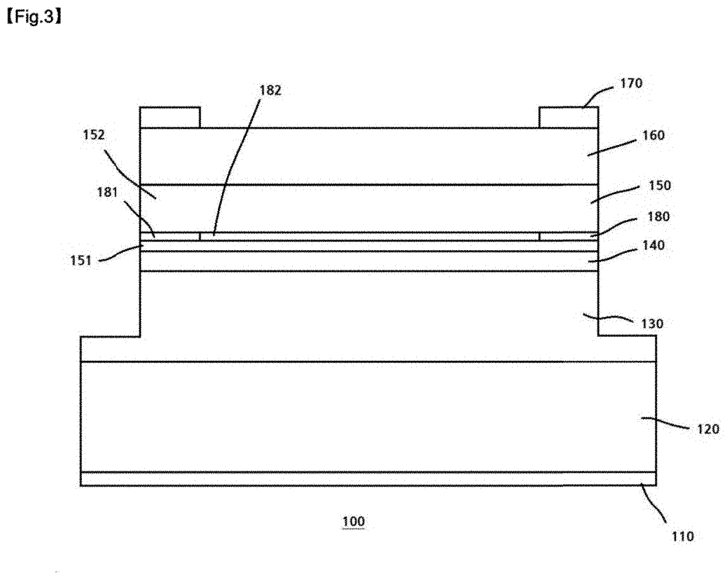

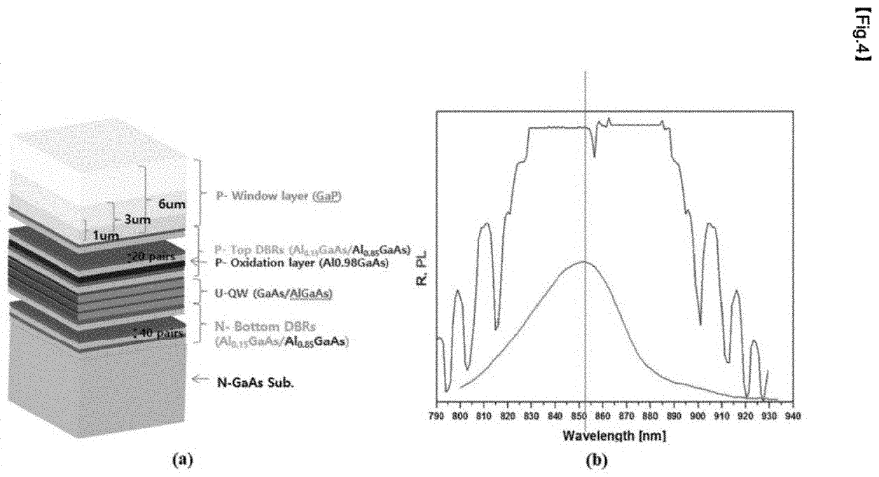

FIG. 3 is a view showing a VCSEL layer structure for emitting a laser beam having a peak wavelength of 860 nm, in which a high conductive GaP barrier layer manufactured by a MOCVD system is applied. As shown in FIG. 3, an oxide VCSEL 100 having a peak wavelength of 860 nm, in which a high conductive GaP barrier layer according to the present invention is applied, is an oxide VCSEL 100 which emits laser beams toward the top of a substrate 120. The substrate 120 is an n-type GaAs substrate. A bottom electrode 110 is provided on the lower surface of the substrate 120.

A bottom n-DBR 130, in which pairs of a high refractive index AlGaAs layer and a low refractive index AlGaAs layer are repeatedly stacked, is provided on the top surface of the substrate 120. An Al_{0.85}Ga_{0.15}As layer and an Al_{0.15}Ga_{0.85}As layer are repeatedly stacked as many as forty times.

An active layer 140 is provided on the bottom DBR 130. The active layer 140 includes a quantum well structure for generating light. The active layer 140 is a GaAs/AlGaAs active layer QW for emitting light having a center wavelength of 850 nm.

A top p-DBR 150 including an oxidized layer 180 is provided on the active layer 140. To avoid damage of the active layer in an oxidization process, the oxidized layer 180 may be inserted between layers of the pairs configuring the p-DBR 150 and may avoid direct contact with the active layer 140. The active layer 140 is stacked on a pair or two pairs of the top DBRs among the twenty pairs, and the other pairs of the top DBR are stacked on the oxidized layer 180.

Accordingly, the top DBR 150 is configured of a first top DBR 151 positioned on the bottom of the oxidized layer 180 and a second top DBR 152 positioned on the top of the oxidized layer 180.

In the same manner as the bottom n-DBR, pairs of a high refractive index AlGaAs layer and a low refractive index AlGaAs layer are repeatedly stacked in the top p-DBR 150, and the top p-DBR 150 is configured of twenty pairs of an Al_{0.85}Ga_{0.15}As layer and an Al_{0.15}Ga_{0.85}As layer.

The oxidized layer 180 is configured of a circular current window (oxidation aperture) 181 formed of Al_{0.98}Ga_{0.02}As having a thickness of about 30 nm at the center and an oxidized ring 182 at the periphery. The DBR reflectivity shows an excellent characteristic of the stop-band shape at almost 98%.

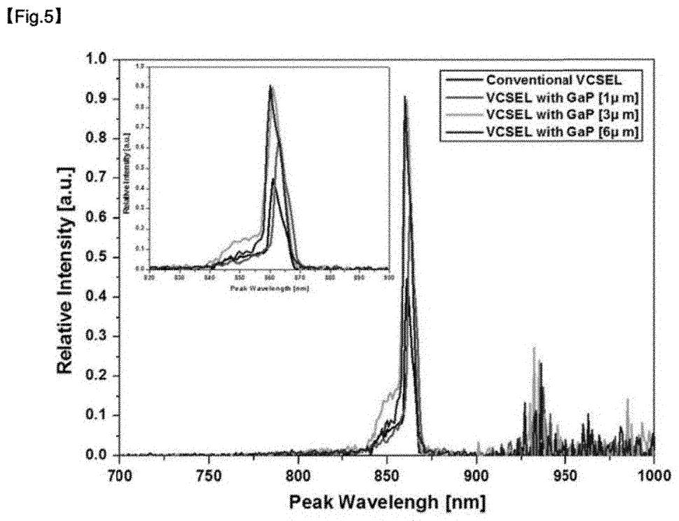

A GaP layer 160 is grown on the top p-DBR 150 in the MOCVD method. As shown in FIG. 4, the GaP layer is grown as much as about 1 μm (embodiment 1), 3 μm (embodiment 2) and 6 μm (embodiment 3), respectively. A top electrode 170 is formed on the top GaP 160 in a ring shape. The peak wavelength of the active layer 140 is about 850 nm, and the cavity peak is about 860 nm by the DBR reflection.

### COMPARATIVE EXAMPLE 1

In the embodiments 1 to 3, the top electrode 170 of a ring shape is formed on the top p-DBR 150 without a GaP layer 160.

Test

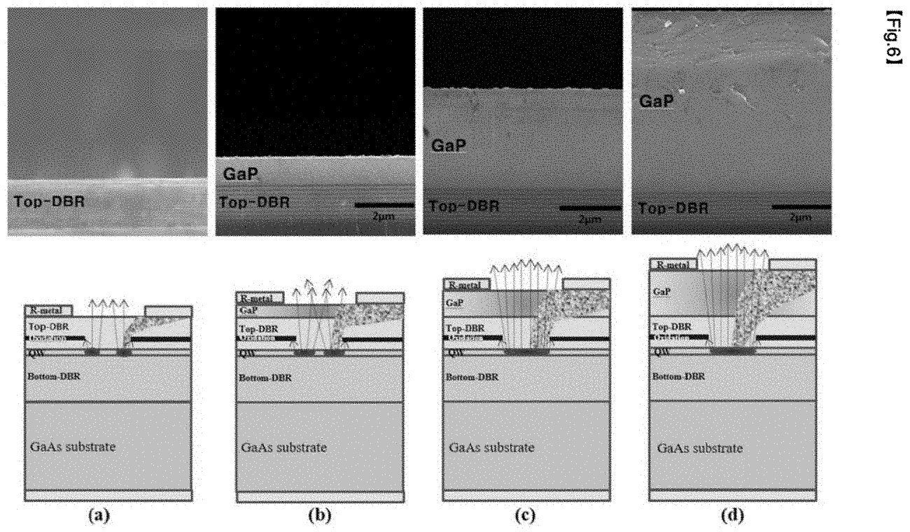

A 20 mA current is applied to a VCSEL without a GaP layer (comparative example 1) and VCSELs to which a GaP barrier having a thickness of 1, 3 and 6 μm is applied (embodiments 1, 2 and 3), and emission intensity is measured. Its result is shown in FIG. 5.

It is confirmed that in the case of a general VCSEL to which a GaP layer is not applied, an intensity of about 0.45 is shown, and the characteristic of low intensity is improved considerably according to application of a GaP barrier and increase in the thickness thereof. When a GaP barrier having a thickness of 1 μm is applied, the intensity is 0.78, which is an increase of about 50% compared with the VCSEL to which the GaP layer is not applied.

Particularly, it is confirmed that when a GaP barrier having a thickness of 3 μm is applied, the intensity is 0.94, showing an increase of about 90%. In addition, it is confirmed that when a GaP barrier having a thickness of 6 μm is applied, the emission intensity is 0.94, showing an increase of about 90%. When a VCSEL to which a GaP barrier of 3 μm or larger is applied, a characteristic almost the same as that of the emission intensity is shown with the increase of thickness, and this is a saturation phenomenon of the emission intensity according to thickness and is determined as having been controlled by a 10 μm diameter of the current window. It is confirmed from this result that application of a GaP barrier greatly increases light efficiency of the 860 nm VCSEL, and it is confirmed that thickness of the GaP barrier is optimized by the oxidation aperture diameter of the VCSEL.

FIG. 6 shows SEM images of the side surfaces of a VCSEL without a GaP layer and 860 nm VCSELs to which GaP barriers of diverse thicknesses are applied and shows mimetic views of current injection paths and light emission.

It is confirmed from the SEM images of FIG. 6 that the GaP barrier is normally grown on the top of the DBR at a thickness of about 1 μm, 3 μm and 6 μm. The current injection path and the light emission effect of a VCSEL structure according to application of a GaP barrier can be confirmed from the mimetic view, and in the case of a VCSEL without a GaP barrier (comparative example 1), a small light emission area is generated along the edge of the limited oxidation layer, in which the current injection path is limited by the current window when current is applied, and accordingly, only a small light emission effect is confirmed.

On the contrary, the current injection path continuously increases when the GaP barrier is applied and the thickness increases, and accordingly, it is confirmed that the light emission area continuously increases, and in addition, the light emission effect is also abruptly enhanced.

Through the mimetic view of the rightmost current injection path and light emission, it is understood that the light emission effect cannot be expected any more when the light emitting area is saturated in an area in which the GaP barrier effect is already limited by the current window at a predetermined thickness. Such a result may support the emission intensity result of FIG. 5.

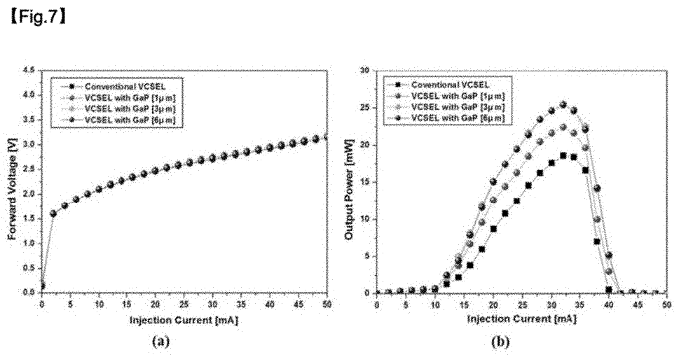

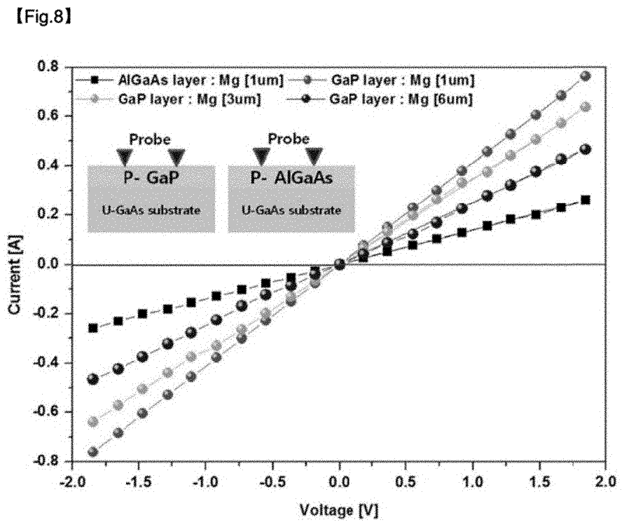

FIG. 7 is a view showing (a) an I-V curve and (b) an I-L curve of VCSELs developed according to application of current 0 to 50 mA in the present invention.

Confirming the (a) I-V characteristic, the I-V characteristics of all the samples are the same without regard to application of a GaP barrier. This is since that conductivity of the GaP is relatively high compared with those of VCSEL materials. On the contrary, confirming the (b) I-L characteristic, it is understood that the light efficiency characteristic is changed significantly according to application of the GaP barrier and change in the thickness thereof.

It is confirmed that light efficiency of a general VCSEL of comparative example 1 is about 17 mW at about 33 mA. When a GaP barrier having a thickness of 1 μm is applied as shown in embodiment 1, light efficiency is about 22.5 mW, which is an increase of about 25%, and when a GaP barrier having a thickness of 3 μm is applied as shown in embodiment 2, light efficiency is about 26 mW, which is an increase of about 40%, and when a GaP barrier having a thickness of 6 μm is applied as shown in embodiment 3, light efficiency is the same as that of applying a GaP barrier having a thickness of 3 μm.

As a result, light efficiency of an 860 nm VCSEL having an oxidation aperture of about 10 μm diameter can be enhanced greatly by the high conductive GaP barrier applied to grow on the top p-DBR, and highest light efficiency can be obtained by a GaP barrier optimized at a thickness of about 3 μm.

According to the present invention, there is provided a new barrier, which is also a current spreading layer, capable of protecting a top DBR in an oxidization process, enhancing flow of current, and passing light of an 860 nm VCSEL.

The oxide VCSEL having a GaP barrier layer according to the present invention enhances light efficiency up to 40% by improving electrode protection and current flow of an 860 nm VCSEL having an oxidation aperture, and an optimum range of efficiency between the applied high conductive material and the oxidation aperture of the VCSEL can be confirmed.

Although the present invention has been illustrated and described in detail in the above drawings and descriptions, it is considered that the drawings and descriptions are illustrative or exemplary and not restrictive. Other changes may be apparent to those skilled in the art from the present invention. These changes may accompany other features that can be used instead of or in addition to the features publicized in this field or described in this specification. Modifications of the disclosed embodiments may be understood and affected by those skilled in the art from learning of the drawings, the present invention and the appended claims. The term “comprising” used in the claims does not exclude other elements or steps, and description of an indefinite article does not exclude a plurality of elements or steps. The fact that particular actions are cited in different dependent claims does not mean that these actions cannot be used to make combinations of the actions advantageous. Arbitrary reference symbols in the claims should not be interpreted as limiting the scope of the claims.

What is claimed is:

1. An oxide vertical cavity surface emitting laser (VCSEL) having a conductive current spreading layer formed between a top electrode and a top distributed Bragg reflector to pass laser having a peak wavelength of 860±10 nm.

2. The VCSEL according to claim 1, wherein the conductive current spreading layer is a non-oxidizing barrier layer.

3. The VCSEL according to claim 2, wherein the non-oxidizing barrier layer is an Al-free layer.

4. The VCSEL according to claim 1, wherein the current spreading layer is a GaP layer.

5. The VCSEL according to claim 1, wherein the GaP layer includes a metallic and/or non-metallic dopant.

6. The VCSEL according to claim 5, wherein the dopant is selected from a group including Mg, Zn and carbon as the dopant.

7. The VCSEL according to claim 5, wherein the GaP layer has a thickness of 1 μm or larger.

8. The VCSEL according to claim 1, wherein the VCSEL includes a bottom electrode, a substrate, a bottom distributed Bragg reflector, an active layer, a top distributed Bragg reflector, a top electrode and an oxidized layer.

9. The VCSEL according to claim 8, wherein the active layer is configured of a GaAs quantum well and an AlGaAs quantum barrier layer.

10. The VCSEL according to claim 8, wherein the thickness of the GaP is 3 μm.

11. The VCSEL according to claim 8, wherein the oxidized layer is positioned between layers of a top p-DBR.

12. The VCSEL according to claim 8, wherein the oxide CSEL operates at a current of 10 to 40 mA.

13. The VCSEL according to claim 8, wherein the top electrode is a transparent electrode selected among indium tin oxide (ITO), ZnO and AZO.

14. The VCSEL according to claim 8, further including an anti-reflection layer on a top of a current spreading layer.
